(19) United States
(12) Patent Application Publication
(10) Pub. No.: US 2021/0028742 A1
(43) Pub. Date: Jan. 28, 2021

(54) HINGED REFELCTORS SOLAR ENERGY SYSTEM

(71) Applicant: Raja Singe Tuli, Montreal (CA)

(72) Inventor: Raja Singe Tuli, Montreal (CA)

(21) Appl. No.: 16/519,118

(22) Filed: Jul. 23, 2019

(51) Int. Cl. H02S 20/32; G01S 3/786; F24S 30/40; F24S 50/20

(52) U.S. Cl. CPC H02S 20/32; F24S 50/20; F24S 30/40; G01S 3/7861

(57) ABSTRACT

The present invention provides a super efficient solar system that is fixed with respect to the Earth in a standard latitude tilt position. The present invention discloses a method for designing and building a motorized means that allow the hinged reflectors to tilt by tracking the movement of the Sun. The rays of the Sun are reflected and concentrated directly onto the fixed solar cells by movable mirrors or reflectors. The solar energy system is composed of a tilted glass panel side-base which makes it possible for the reflectors to tilt. The multiple components within the solar energy system cooperate to continually concentrate the incoming solar radiation on the solar cells as the Sun runs its course across the sky.

### BACKGROUND

### Field of the Invention

The present invention pertains generally to systems that employ energy converting units, such as photovoltaic cells, to harness solar energy. More particularly, the present invention pertains to a solar energy concentrating system where hinged reflectors tilt with respect to Sun tracking; this is done in order to provide maximum solar radiation to the solar cells. The invention relates to several embodiments of efficient solar tracking hinged reflectors in the solar energy systems.

### Description of Related Art

Existing techniques for tracking the Sun rely typically on one or more of the following methods. The diurnal motion of the Sun is well understood, and consequently, a telescope, for example, can be mounted on an accurately aligned altazimuth or equatorial mount. The axial drives of that mount are then computer controlled to maintain the telescope in an orientation that will point the objective lens or mirror of the telescope at the Sun's calculated position.

This approach, however, requires the highly accurate initial alignment of the mount. Such installation time and expense may not be acceptable in applications, such as the installation of solar power collectors on a mass scale.

Another existing approach is so-called shadow bar Sun sensing, in which a pair of sensors are mounted on a solar radiation collector (such as a dish or plane mirror) between a shadow bar. The shadow bar casts a shadow on one of the sensors if the collector is not pointing directly at the sun. The collector's attitude can then be adjusted on the basis of the outputs of these sensors until those outputs are equal.

These existing approaches, however, make no allowance for the subsequent effects of imperfect manufacturing tolerances on the orientation of the radiation receiver (to which the collector directed collected radiation) relative to the collector itself. The effect of such imperfections will also vary with the changing position of the sun and orientation of the collector, even if the receiver is fixed with respect to the collector.

The present invention provides, therefore, a solar tracking system for translating the alignment of collectors in an instrument with respect to the Sun, said instrument having a solar radiation receiver or solar cell and a solar radiation collector or mirror for collecting maximum solar radiation and directing said radiation towards said receiver.

### BRIEF SUMMARY OF THE INVENTION

The problem of energy supply at a reasonable cost has never been completely solved. As the worldwide demand for energy increases exponentially, there is a heavy burden placed on traditional energy sources of energy. The spiraling cost of energy in recent years adversely affects the household economy. Therefore, alternate sources of energy, e.g., solar power, have become increasingly attractive in recent times. Solar panels, i.e. arrays of photovoltaic cells arranged in panels, are in increasing use today. The use of such photovoltaic cells is expected to accelerate as the cost of the cells decreases.

Various forms of solar trackers are also well known, for use with arrays or panels of photovoltaic cells. However, in the scope of the present invention, the most efficient trackers, for absorbing maximum sunlight in a given day, are tilting reflectors, which tilt while taking into account both the azimuth variation (progression of the Sun's bearing angle, i.e. east to south to west), and the Sun's change in elevation angle from the horizon.

For a preferred embodiment of the present invention, the solar energy system is essentially fixed with respect to the Earth in a standard latitude tilt position. It consists of two side bases, a metal base plate, a glass top plate, and at least six solar panels in the preferred embodiment. Each solar panel compromises of at least two reflectors and an array of fixed solar cells in the principal embodiment. The size of the said solar cells can vary. The shape of the said reflectors will be the same. It is intended that the present invention will harness the maximum amount of solar light to reach the said solar cells.

As per a preferred embodiment of the present invention, the solar energy system includes an array of solar cells connected to each other in series, around the array there are two sides of independent hinged mirrors which are configured on the support surface. Each set of mirrors have a right-sided mirrors and a left-sided mirrors exposed to sunlight to form a plurality of reflecting surfaces. Hinge mechanism for each mirror connects the mirrors separately to the support surface. The support surface and the solar cells are not movable with the Earth, they are stationary.

According to an aspect of the present invention, each solar panel comprises a set of hinged mirrors: a right-sided mirror and a left-sided mirror in the preferred embodiment. The said mirrors tilt individually because each one is adjusted in order to capture the maximum sunrays and reflect it down to the said solar cells. In order to effectively track the relative movement of the Sun, it is clear that both the azimuthal movements and elevation considerations for a solar panel are important. In the present invention, the reflectors are tilted while taking into account both the Sun azimuth and elevation angle. The said reflectors are adjusted with respect to the elevation axis to optimize the angle of incidence for maximal energy collection.

Another aspect of the present invention is that one side-base is made of a tilted glass panel which allows the mirrors or reflectors to tilt based on solar tracking during the day and different seasons of the year. In turn, this will allow the highest concentration of sunlight to be reflected on to the solar cells.

A motor is provided for the apparatus of the present invention to tilt the said reflectors to correspond with changes in the Sun's position throughout a daylight period. The main benefit of tilting reflectors or mirrors is to move the said mirrors accordingly with solar tracking data to harness maximum solar input and, hence, give the advantage to use fewer solar cells. The said tilting mirrors move with the Sun, facing towards it as it changes its position during a daylight period and during the different seasons. The elevation angle of the Sun changes as the Sun ascends and descends, and the horizontal angle of the Sun changes with the movement of the Sun from horizon to horizon.

Another objective of the present invention is to provide a good heat sink for the said solar cells. The said objective is accomplished by having the said solar cells fixed to a metal base plate.

As intended for the present invention, multiple solar energy systems can be placed adjacent to each other in a row in the preferred embodiment. The solar panels within the said solar systems can be tilted together through a motorized means with respect to the tracking of the Sun. Right-sided panels will be tilted separately from the left-sided panels, again to maximize solar input. Performing this process repeatedly yields the advantageous result that the said reflectors remain substantially aligned with the Sun's rays. Other embodiments can have multiple such rows of solar energy systems.

Another objective of the present invention is that the side glass panel can be curved instead of being flat to allow the said mirrors to tilt even more. This helps to capture more solar energy and reflect it efficiently onto the said solar cells.

Other embodiments of the present invention can have additional solar cells on each side of the said reflectors.

The above as well as additional features and advantages of the present invention will become apparent in the following detailed description and the features of novelty which characterize this invention will be pointed out with particularity in the claims annexed to and forming a part of this specification.

### BRIEF DESCRIPTION OF THE DRAWINGS

FIG. 1 shows a view of a solar energy system or box.

FIG. 2 illustrates the Earth's tilt position during different seasons.

FIG. 3 demonstrates how the hinge tilts the reflector.

FIG. 4 shows a cross-sectional view of the hinge.

FIG. 5 illustrates the Vernal & Autumnal Equinox sunrays striking the solar system.

FIG. 6 depicts sunrays striking the solar system during Summer Solstice.

FIG. 7 shows sunrays striking the solar system during Winter Solstice.

FIG. 8 illustrates the mechanism of motorized rods to move the mirrors.

FIG. 9 demonstrates a cross-sectional view of the motorized rod.

FIG. 10 depicts another method that uses a hinge to tilt the mirrors.

FIG. 11 illustrates a solar energy system containing multiple rows of panels.

FIG. 12 demonstrates adjacent solar energy systems and how they work.

FIG. 13 shows adjacent solar energy systems with termination units.

FIG. 14 depicts how the sunrays are reflected from the termination unit and the solar panel to reach the solar cell.

FIG. 15 shows how the inclined glass mirror affects the passage of sunrays when two solar energy systems are placed next to each other.

FIG. 16 illustrates how the inclined glass mirror affects the passage of sunrays when two solar energy systems are placed further apart from each other.

FIG. 17 demonstrates that the inclined glass mirror can be curved instead of being flat.

FIG. 18 depicts how multiple solar energy systems can be moved together.

FIG. 19 shows the addition of extra solar cells in a solar energy system.

### DETAILED DESCRIPTION OF THE EMBODIMENT

The invention will now be described herein with reference to the figures. The figures are intended to be illustrative rather than limiting and are included herewith to facilitate the explanation of the invention.

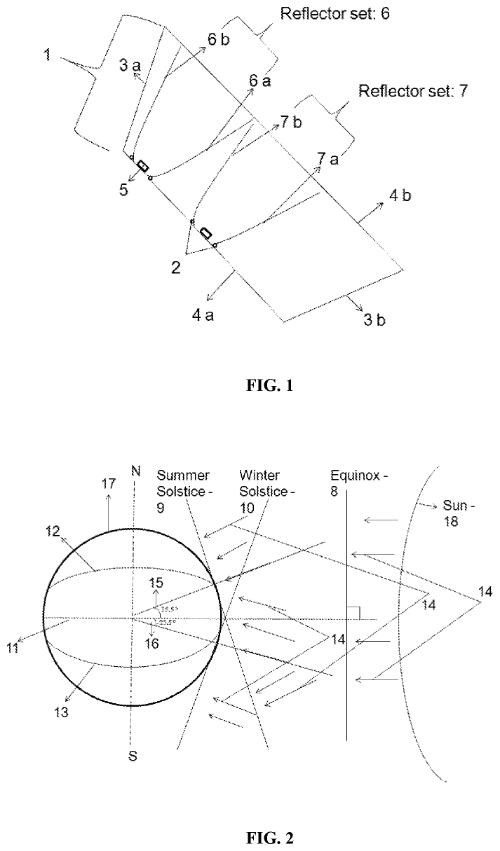

FIG. 1 illustrates a diagram of a box or solar energy system 1. The preferred embodiment of the present invention is composed of a box 1 which is fixed with respect to the Earth in a standard latitude tilt position. The box 1 contains the following: two side bases 3a and 3b, one of them 3a being made of glass, a metal base plate 4a, and a glass top plate 4b. Inside the box 1, there are multiple solar panels. In the primary embodiment, there are at least six solar panels wherein each panel consists of the following: one set of two independent, hinged mirrors 6a and 6b and an array of solar cells 5 that generate electricity. The solar cells 5 are all connected in series, and the hinges 2 are placed on the outer sides of both mirrors; for example, reflector set 6 has a hinge 2 on the right sided mirror 6 a and another hinge 2 on the left sided mirror 6b. Likewise reflector set 7 has a hinge 2 on the right sided mirror 7a and another hinge 2 on the left sided mirror 7b, and so on. The hinges 2 allow the reflectors 6 and 7 to pivot in the direction of the Sun, to receive optimum sunlight for power generation. For the sake of simplicity, only two sets of independent reflectors 6 and 7 have been drawn in this illustration of the primary embodiment. In the preferred embodiment, there are at least six sets of reflectors. In contrast to the principal embodiment, there can be fewer or more sets of reflectors within one solar energy system in other embodiments. The metal plate 4a provides a very good and efficient heat sink for the solar cells 5. The side walls 3a and 3b are also kept at an angle from the base plate 4a so as to create a tub like structure within which the hinged mirrors or reflectors 6 and 7 are kept. The reason for the inclination of the side walls 3a and 3b is to allow the mirrors to tilt or move in such a position as to focus and concentrate the maximum amount of light input onto the solar cells 5. In this invention, the goal is to maximize the amount of light concentration so fewer solar cells are used in comparison to the prior art. Each of the two reflectors 6 and 7 has a curve-shaped mirror surface that move to face the sunrays and reflect them back on to its corresponding solar cells 5. Furthermore, the solar system 1 is placed in a standard latitude tilt position that is fixed with respect to the Earth. The Earth's axis of rotation is tilted at an angle of 23.5° with respect to its orbit around the Sun. Hence, at the equator, the panels will be lying flat on the ground, whereas at the Tropic of Cancer, the panels will be lying at an angle of 23.43695° (approximately)23.5°. For example, in Montreal, Canada, the panels will be tilted at 45° since Montreal's latitude tilt is 45.5°. The angle or tilt of a solar panel is an important consideration. Together with the Earth's daily rotation and yearly revolution, it accounts for the distribution of solar radiation over the Earth's surface, the changing length of hours of daylight and darkness, and the changing of the seasons.

Referring to FIG. 2, it demonstrates the inclination of the Earth's axis and the direction of the sunrays 14. The inclination causes the sunrays 14 to hit the Earth 17 at an angle. Our Earth 17 rotates on its own axis once each day, producing the cycle of day and night. At the same time, it revolves around the Sun 18 on its orbit over the course of a year. As the Earth 17 revolves round the Sun 18, the tilting of the Earth's axis causes the formation of seasons. The axis of rotation of the Earth 17 is not lined up with the axis of motion around the Sun 18, instead being tilted slightly at 23.5°. The surfaces of the world receive different amounts of sunlight because the Earth 17 is spherical and because of the tilt of the Earth's axis. This tilt stays fixed in space meaning that during one half of the year, the Northern Hemisphere of the Earth 17 is tilted slightly towards the Sun 18 while the Southern Hemisphere is tilted away and for the other half of the year, the reverse is true. The great distance of the Sun 18 to the Earth 17 results in rays from the Sun 18 that are essentially parallel to one another as they strike the surface of the Earth 17. If Earth's Northern Hemisphere is tilted towards the Sun 18, then, it receives the most direct rays of the Sun 14 (that is, the angle of incidence of sunrays is higher), and it is Summer in the Northern Hemisphere. If Earth's Southern Hemisphere is tilted towards the Sun 18, then, it will receive the most direct rays of the Sun 14 (that is, the angle of incidence of sunrays is higher), and it is Summer in the Southern Hemisphere. Thus, on the occasion of the Summer Solstice 9, the sunrays 14 hit directly on the Tropic of Cancer 12 in the Northern Hemisphere, making an angle of 23.5° 15 with the equatorial plane 11. At this time of the year, there will be Summer in the North while it is Winter in the South. In regards to the Winter Solstice 10, the sunrays 14 shine down most directly on the Tropic of Capricorn 13 in the Southern Hemisphere, making an angle of −23.5° 16 with the equatorial plane 11. In contrast to the former, the scenario has turned around, and it is Summer in the South while Winter takes over in the North. There is a position called Vernal and Autumnal Equinox 8, occurring halfway between Summer and Winter. During this time, both poles are equidistant from the sun and all points on the Earth's surface have 12 hours of daylight and 12 hours of darkness. In this position 8, light comes in perpendicular from the Sun 18. At these two points of the year, the sunrays 14 will illuminate the Northern and Southern Hemispheres equally, making an angle of 0° with the equatorial plane 11. Thus, depending on various seasons, the angle of incidence of sunrays at the equator 11 varies from +23.5° to −23.5°. Any specific location in the Northern Hemisphere of Earth 17 during Winter will receive sunrays 14 at angle which is equal to the sum total of latitude of that location, plus Earth's angle of inclination, plus 90°. Thus, at the equator during Winter in the Northern Hemisphere, the angle at which sunrays 14 will hit the equator will be 113.5° (0°+23.5°+90°). Similarly, during Winter, Tropic of Cancer 12 will receive sunrays 14 at an angle of 137° (23.5°+23.5°+90°). The Vernal and Autumnal Equinox 8 happens such that an equal amount of sunshine falls on both the Northern and Southern hemispheres of the Earth 17.

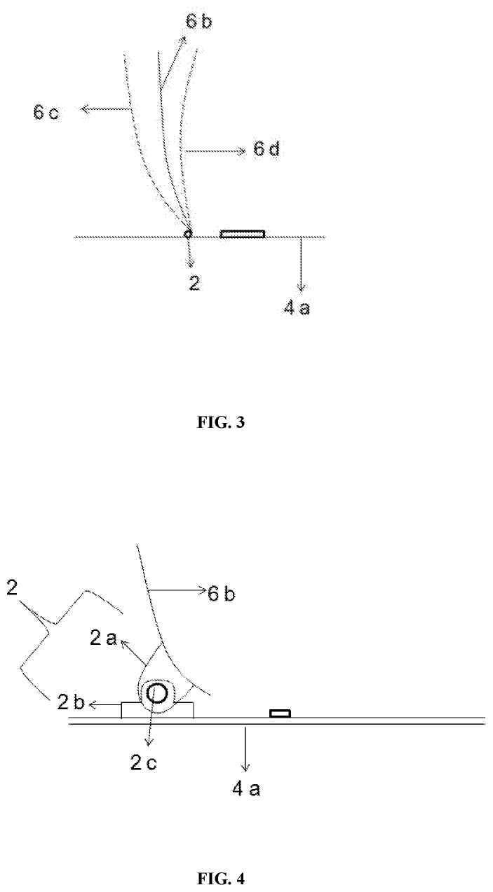

Referring to FIG. 3, only the left-sided mirror 6b has been drawn for the sake of simplicity. Both the left-sided reflector 6b and the right-sided reflector 6b are connected to a hinge on each side, separately. The hinge 2 itself is connected to the metal plate 4a of the solar energy system. The reflector 6b does not touch the metal plate 4a. The hinge 2 makes it possible for the reflector 6b to tilt to both the right and left sides. In this diagram, when the reflector 6b tilts to the right side, it moves to position 6d, and when it tilts to the left side, it moves to position 6c, for instance.

FIG. 4 shows a cross-sectional view of the hinge 2 mechanism. The hinge 2 consists of two plastic plates or parts 2a and 2b, wherein part 2a is connected to part 2b. Both plates 2a and 2b are joined by a pin 2c about which both plates are free to turn. They rotate relative to each other about a fixed axis of rotation and thus allow the reflector 6b to tilt.

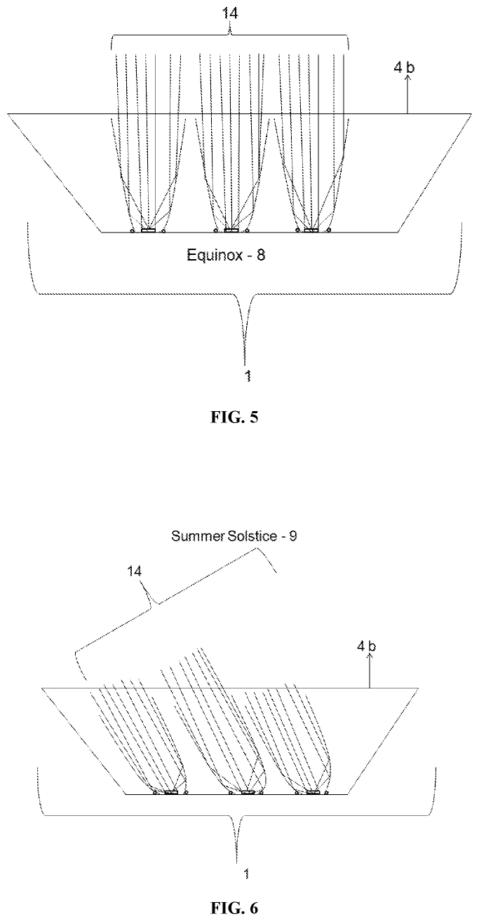

FIG. 5 illustrates how the sunrays 14 strike the solar energy system 1 during Equinox 8, which is halfway between Summer and Winter. The solar system 1 is placed in a standard latitude tilt position that is fixed with respect to the Earth in the preferred embodiment of the present invention. During Equinox 8, the sunrays 14 come in straight, perpendicular to the top glass 4b of the solar energy system 1. A solar system will harness the most power when the sunrays 14 hit its surface perpendicularly. When the sunrays 14 are perpendicular to an absorbing surface, the irradiance incident on that surface has the highest possible power density. As the angle between the Sun 18 and the absorbing surface changes, the intensity of light on the surface is reduced. To counteract this phenomenon, in the present invention of the preferred embodiment, both the right-sided and left-sided mirrors will tilt separately to track the Sun 18 which will thus enable them to collect and reflect a higher amount of solar radiation than within a fixed module. In the principal embodiment, both reflectors are positioned in such a way that they will do their job at directing and concentrating the maximum amount of sunlight 14 down to the solar cells 5.

In regards to FIG. 6, it demonstrates how the sunrays 14 come in during Summer Solstice 9. In this second scenario of Summer Solstice 9, sunrays 14 that hit the Earth 17 make an angle of 23.5° with the top glass 4b of the solar energy system 1. In this case, in the primary embodiment of our current invention, the mirrors are independently tilted a little to the left through a motorized means, and track the Sun 18. The purpose of this is to allow the tracking reflectors to capture and reflect the maximum solar radiation onto the solar cells 5. In designing photovoltaic (PV) systems, the question of how much available irradiance is absorbed by the solar cells is very important, since the amount of energy the system is able to produce is directly proportional to the amount of energy it absorbs from the Sun 18. Therefore, the present invention is designed with hinged reflectors, which tilt based on the Sun's movement across the sky, maximizing the amount of sunlight that hits the reflectors and ensuring that it reaches the said solar cells 5. In the preferred embodiment, the right-sided mirrors move together independently from the left-sided mirrors, making sure that they both are facing the Sun 18. In our invention, there is a motor and electronics for tracking the Sun 18, and an algorithm that knows where to position the mirrors in order to capture the greatest sunlight concentration. It is essential that the motors and mechanics continue to move and adjust the reflectors separately in order to ensure that both mirrors can individually capture as much solar radiation 14 as possible, and, in turn, reflect it 14 onto the said solar cells 5 from both sides. For example, during Summer Solstice, the mirrors tilt a little to the left, stay there, then, come back, and tilt again; this calibration is repeated every so often in order to guarantee that the best light input will reach the said solar cells 5.

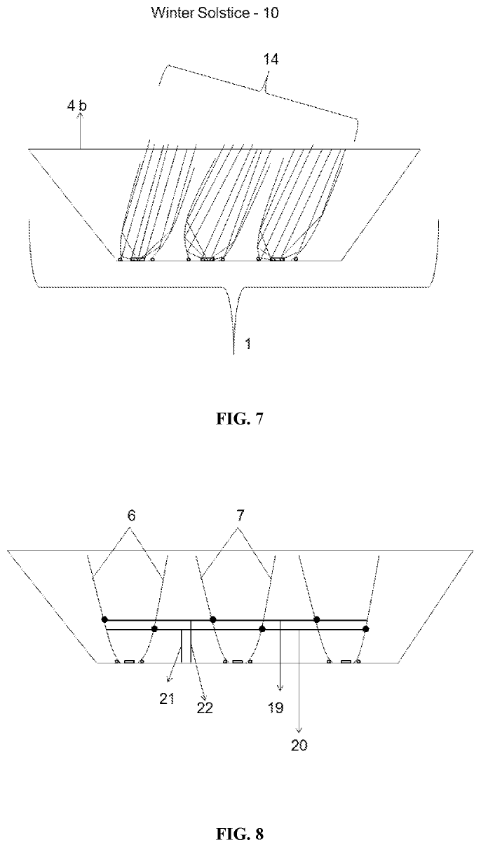

FIG. 7 depicts how the sunrays 14 strike the mirrors during Winter Solstice 10. At this time, the position of the sunrays 14 will make an angle of −23.5° with the top glass 4b of the solar energy system 1. In the principle embodiment of the present invention, the mirrors are tilted a little to the right in this scenario. The advantage of this is that all the light that comes in gets concentrated onto the solar cells 5, making it a cheaper approach because we are using far less solar cells. In the preferred embodiment, the left-sided mirrors move all together separately from the right-sided mirrors; both set of reflectors move independently at different times of the day and during the seasons. They adjust themselves according to the positioning of the sunrays 14 so as to receive the most sunlight in the best optimal way.

Additional structural aspects of the present invention will be best appreciated with reference to FIG. 8 where it can be seen the placement of two independent connecting rods 19 and 20 in the preferred embodiment. One rod 20 connects the right-sided mirrors together, while the second rod 19 joins the left-sided mirrors together for multiple panel movement. In addition to this, there are two motorized rods 21 and 22, connected to the above-mentioned rods 19 and 20, which tilt the mirror sets 6 and 7 via a motorized means. Rod 21 moves the right-sided reflectors together, but separately from the left-sided mirrors. Rod 22 tilts the left-sided reflectors together, again separately from the right-sided ones. This process allows for the movement of multiple panels within a solar energy system at a given time in order to collect and reflect maximum solar radiation onto the solar cells.

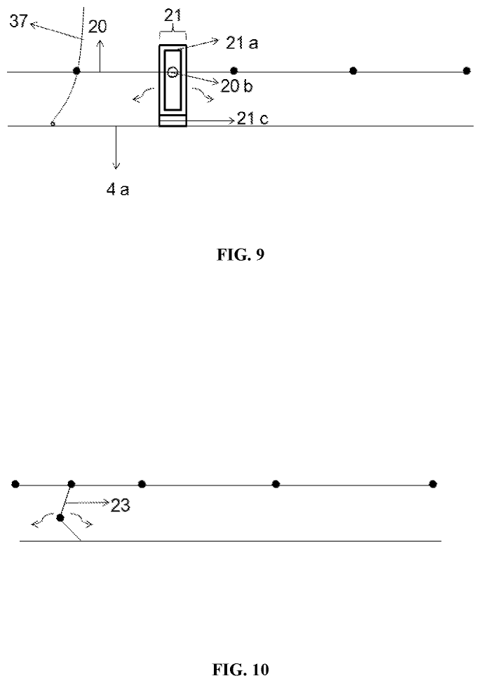

FIG. 9 depicts a cross-sectional view of a motorized rod 21 that is responsible for tilting the reflectors in the preferred embodiment. The motorized rod 21 is further divided into the following sections: Part 21a is a slotted piece in which a bolt or pin 20b will slot into place, and part 21c consists of a motor. The bolt 20b is integrated into rod 20, which connects the right-sided mirrors, in this example. For the sake of simplicity, only one motorized rod 21 has been drawn that will be responsible for tilting the right-sided reflectors which are connected to rod 20 in this example. In reality, there are two motorized rods, one responsible for tilting the right sided reflectors, and the other responsible for tilting the left sided mirrors. This will allow the reflectors to individually capture maximum solar radiation and reflect it onto the solar cells in the solar energy system. In the preferred embodiment of the present invention, the mechanism that works to tilt the mirrors is as follows. First, the motor 21c turns, and then the motorized rod 21 turns. As the slotted piece 21a moves, it causes the pin 20b and rod 20 to move along, thus, allowing the mirrors to tilt right or left. For instance, if the reflector 37 in the illustration were to tilt to the right, the position of rod 20 and the pin 20b will move a little to the right and further down, but the position of pin 20b with respect to the slotted piece 21a will be at a higher position in the slot than compared to its starting position. A higher position of the pin 20b in the slotted piece 21a means a lower positioning point of the rod 20. When the slotted piece 21a rotates, it forces the horizontal rod 20 to translate or move horizontally and vertically and thus provides a slotted means to tilt the reflectors left and right.

FIG. 10 illustrates that a hinged means 23 may be used in another embodiment to tilt the reflectors right or left instead of a slotted means in the primary embodiment as explained in section 00046.

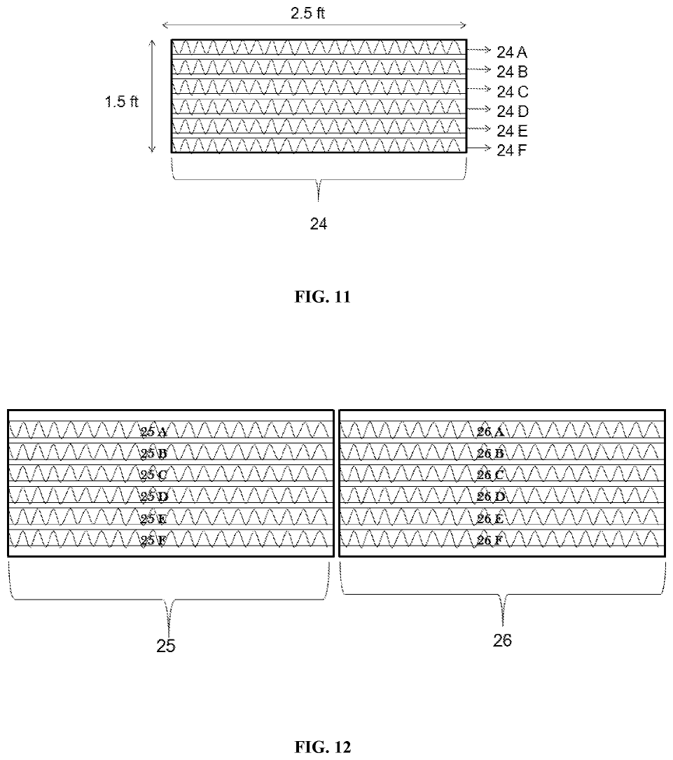

FIG. 11 illustrates the diagram of the solar energy system 24 as a whole that is fixed with respect to the Earth in standard latitude tilt position. For the sake of understanding only, in the preferred embodiment of the current invention, six rows of solar panels 24A-24F are shown. Viewing the solar system 24 from the top, its dimensions are 2.5 ft by 1.5 ft. In other embodiments, there can be additional rows of solar panels. Each one of the solar panels 24A-24F has two tilting reflectors and an array of high-efficiency solar cells; the solar cells are also fixed with respect to the Earth. In the principal embodiment, there is a right-sided and left-sided reflectors present in each panel, and they both tilt individually by tracking the Sun; they do their job at reflecting and focusing maximum solar radiation on to their corresponding solar cells.

FIG. 12 shows two solar energy systems 25 and 26 that are attached in series to each other in the preferred embodiment of the present invention. The multiple solar systems 25 and 26 are placed adjacent to each other in a row and multiple such rows can be present in the solar energy network. In the principal embodiment, each solar system has six solar panels; for example, solar system 25 contains six panels numbered 25A-25F, Likewise, there are six solar panels numbered 26A-26F for the corresponding solar system 26. In other embodiments, there can be more or fewer solar systems connected to each other in a single row, or they can even be present in multiple rows.

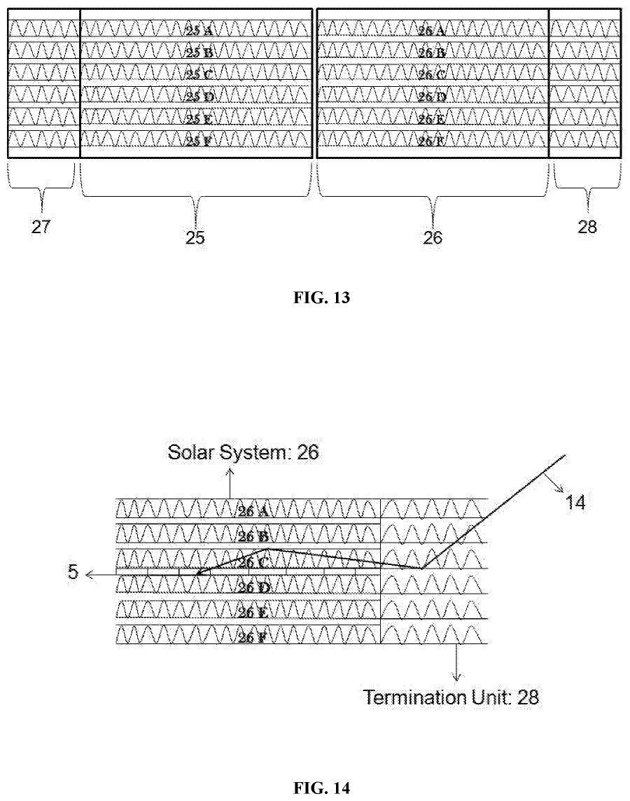

FIG. 13 demonstrates one row of multiple solar energy systems attached in series, wherein each solar system has multiple solar panels in the preferred embodiment of the current invention. In this illustration, there are two solar energy systems 25 and 26 connected to each other in series and fixed in standard latitude tilt position with respect to the Earth; the solar cells are also connected in series and fixed with respect to the Earth. The only pieces that move are the reflecting mirrors. In addition, there are six solar panels in each solar system, wherein, each solar panel is compromised of two mirror sets. Each mirror set consists of one right-sided mirror, one left-sided mirror, and an array of solar cells in the preferred embodiment. Each reflecting mirror is identical in shape and orientation. Altogether, there are 12 mirrors for all six solar panels, six right-sided and six left-sided mirrors in the principal embodiment. The solar systems 25 and 26 must have an end unit known as a termination unit in the preferred embodiment. In this figure, there are two termination units 27 and 28 at both ends of the solar energy system row; one at the beginning of the row and one at the end. The termination units 27 and 28 are made up of glass in the primary embodiment and only contain a smaller number of reflectors than those present in the solar panels. However, in contrast to the solar panels, the end units 27 and 28 do not contain any solar cells. The purpose of these termination units 27 and 28 is to supply oblique light rays. In other embodiments, for example, if there are 10 or 20 solar systems connected together in series, then, there must be a termination unit on both ends of the system series. In other embodiments, there can be multiple such rows of solar energy systems. Also, the space between each row of solar systems is kept such that a row of solar systems does not obstruct sunrays from reaching its neighbouring systems.

FIG. 14 illustrates the role a termination unit 28 plays in the solar energy system 26. The termination unit 28 contains only a small number of reflectors and does not contain any solar cells. When a ray of light 14 strikes the termination unit 28, it reflects off it, then, it strikes the solar panel 26C. The ray of light 14 then reflects off the solar panel 26C and is focused onto the solar cells 5. This solar system 26 has a glass termination unit on both ends allowing light to pass through.

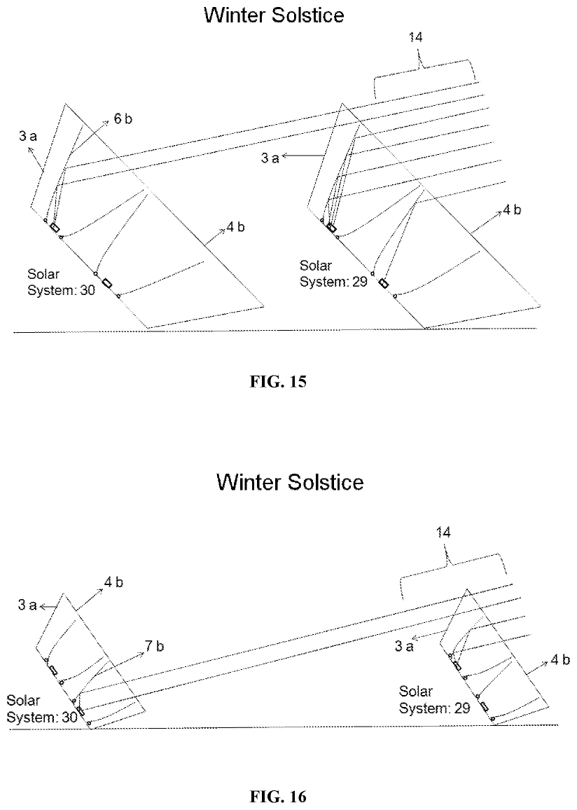

FIG. 15 depicts two solar systems 29 and 30 that are placed in two separate rows unlike in the previous FIG. 12 where there was one row of two solar systems. In the primary embodiment of the present invention, the inclined side-base 3a and the top plate 4b has to be made of glass because glass makes it possible for the sunrays 14 to pass from the first solar system 29 to the second solar system 30. The next solar system that is going to be installed in another row needs to get the light, and the glass from the previous system will allow that to happen. This is vital so as not to waste the sunrays 14. In addition to this, the side base 3a is inclined to allow the mirrors 6 and 7 to turn in order to allow absorption of maximum sunlight 14. In this example, two solar systems 29 and 30 are shown that are placed close to each other and how light travels through them during the Winter Solstice 10 in the primary embodiment. The light 14 from the first solar system 29 will pass through its side glass 3a; then, it will pass through the top glass plate 4b of the second solar system 30. Next, it will strike the left mirror 6 on the farthest left side, and reach all the way down to the solar cell 5.

Referring to FIG. 16, it clearly shows how glass allows the light to pass through multiple solar energy systems during Winter Solstice. In the principle embodiment of the current invention, when the systems are placed further apart from each other, the light 14 from the first system 29 will pass through its side glass 3a, then, pass through the top glass plate 4b belonging to the second solar system 30. Next, it will strike the left mirror 7 on the farthest right side, and reach all the way down to the solar cell 5.

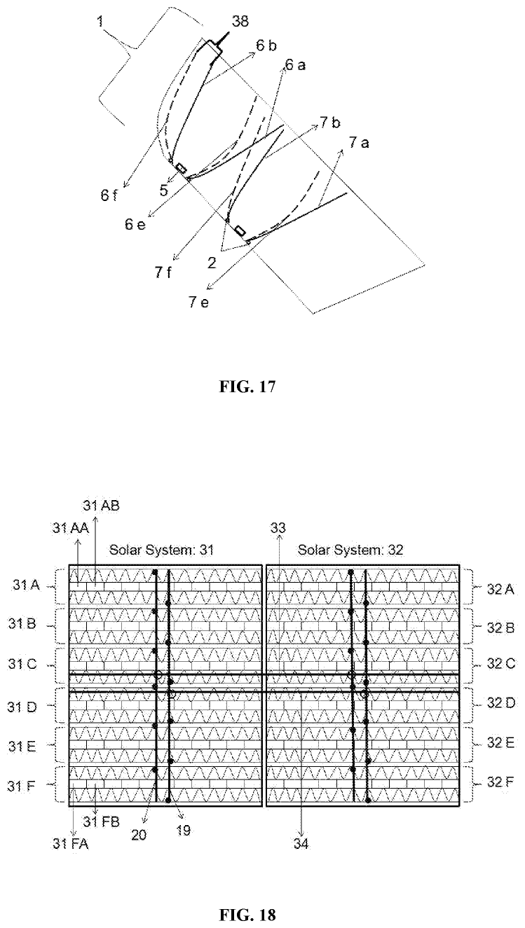

FIG. 17 depicts the fact that in another embodiment, the side glass 3a can be curved instead of being flat like in the preferred embodiment. The advantage of this embodiment is that the mirrors can tilt even more, allowing more sunlight to pass through and be captured. As can be seen in this diagram, in the preferred embodiment, the left-sided mirrors will change positions, moving from positions 6a and 7a to positions 6e and 7e, respectively. The right-sided reflectors will also change positions from 6b and 7b to position 6f and 7f, respectively. In this way, the individual reflectors have tilted even farther than in the preferred embodiment; the extra space 38 is not wasted and full use of maximizing solar input can be utilized.

FIG. 18 shows the top view of two solar energy systems 31 and 32 placed adjacent to each other in the principal embodiment of the present invention. Each system consists of six panels. For example, the first system 31 has six panels numbered 31A-31F, wherein each panel has two reflectors in the preferred embodiment. Similarly, the second system 32 is also composed of six panels numbered 32A-32F, each panel having two reflectors. In the preferred embodiment of the current invention, we have two motorized rods 33 and 34, independent of each other, which allow for multiple panel movement within multiple solar systems. These motorized rods 33 and 34 are connected to the other two rods 19 and 20, which connect the right and left sided reflectors across multiple solar systems. Hence, the motors and levers cause one motorized rod 33 to tilt the right sided mirrors and the other motorized rod 34 to tilt the left sided mirrors within both solar energy systems 31 and 32. It forms like an H symbol, rotating the right and left mirrors independently. Other embodiments can have multiple such solar energy systems, and the motorized rods will do their job at accurately tilting the reflectors for optimum solar radiation collection.

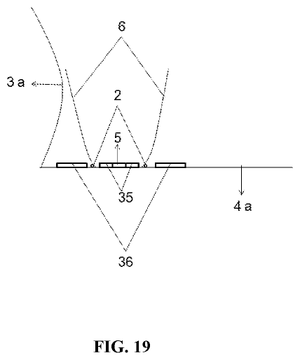

Referring to FIG. 19, it illustrates that there can be additional solar cells that are added to the solar system in another embodiment. In the primary embodiment, the hinges 2 are connected to the same metal plate 4a that the solar cell 5 is fixed to. There is a small gap between the solar cell 5 and the hinged mirror 6 in the preferred embodiment. If light is struck at this gap missing the solar cell 5, then that amount of light will be wasted in the standard position. To make up for this, we can add extra solar cells 35, covering this gap or make the current solar cell 5 wider in order to make it more solar efficient. This approach will be more costly, but it will prove to be more efficient in terms of capturing extra solar radiation. Hence, the pros outweigh the cons. In other embodiments, the solar cells 36 may be placed on both outer sides of the reflector 6 as well.

I claim:

1. A solar energy concentrator system comprising:
a support surface;
at least a set of concentrating reflectors comprising two independent mirrors configured on said support surface, said two independent mirrors having a right-sided mirrors and a left-sided mirrors exposed to sunlight to form a plurality of reflecting surfaces;
hinge mechanism for each independent mirror separately connecting said mirror to the support surface;
an array of solar cells configured on said support surface between said two independent mirrors, wherein said two independent mirrors tilt individually during operation and are adjusted to converge sunlight down to said solar cells for maximal solar energy collection.

2. The solar energy concentrator system as claimed in claim Error! Reference source not found. wherein the support surface is a metal base plate providing heat sink for the solar cells.

3. The solar energy concentrator system as claimed in claim Error! Reference source not found. wherein further comprises two side bases and a top plate.

4. The solar energy concentrator system as claimed in claim 3 wherein at least one of said two side bases and said top plate are made of glass to allow the sunlight to pass though multiple said solar energy concentrator systems.

5. The solar energy concentrator system as claimed in claim 3 wherein said two side bases are curved to allow said concentrating reflectors to tilt or move.

6. The solar energy concentrator system as claimed in claim Error! Reference source not found. wherein said concentrating reflectors have a curve-shaped surface that reflect the sunlight down to said solar cells.

7. The solar energy concentrator system as claimed in claim 6 wherein said two independent mirrors are identical in shape and orientation.

8. The solar energy concentrator system as claimed in claim Error! Reference source not found. wherein the hinge mechanism is a hinge which consists of two plastic parts joined by a pin to allow the mirrors to tilt.

9. The solar energy concentrator system as claimed in claim 8 wherein the left-sided mirrors and the right-sided mirrors are connected separately to a hinge on each side.

10. The solar energy concentrator system as claimed in claim Error! Reference source not found. wherein a connecting rod connects the right-sided mirrors together, a second connecting rod connects the left-sided mirrors together for multiple movement, and said two connecting rods connect separately with two motorized rods.

11. The solar energy concentrator system as claimed in claim 10 wherein a motor is provided to tilt said reflectors.

12. The solar energy concentrator system as claimed in claim Error! Reference source not found. wherein further comprises a termination unit on each end of the system, said termination unit contains said right-sided mirrors and said left-sided mirrors but does not contain any solar cells.

13. The solar energy concentrator system as claimed in claim Error! Reference source not found. wherein extra array of solar cells is added to cover the gap between two sets of the concentrating reflectors.

14. The solar energy concentrator system as claimed in claim Error! Reference source not found. wherein further comprises some electronics and an algorithm to position the mirrors in order to reflect maximum sunlight.

15. The solar energy concentrator system as claimed in claim Error! Reference source not found. wherein multiple said systems are connected to each other in a single row or are present in multiple rows.
